(19) United States
(12) Patent Application Publication
(10) Pub. No.: US 2010/0155728 A1
(43) Pub. Date: Jun. 24, 2010

(54) EPITAXIAL WAFER AND METHOD FOR FABRICATING THE SAME

(75) Inventor: Han-Seob Cha, Chungcheongbuk-do (KR)

Correspondence Address: MORGAN LEWIS & BOCKIUS LLP, 1111 PENNSYLVANIA AVENUE NW, WASHINGTON, DC, 20004, US

(73) Assignee: MagnaChip Semiconductor, Ltd.

(21) Appl. No.: 12/619,043

(22) Filed: Nov. 16, 2009

(30) Foreign Application Priority Data
Dec. 24, 2008 (KR) 10-2008-0133881

(51) Int. Cl. H01L 29/12; H01L 21/20

(52) U.S. Cl. 257/49; 438/491; 257/E29.068; 257/E21.133

(57) ABSTRACT

An epitaxial wafer and method for fabricating the same can prevent a bowing phenomenon of the epitaxial wafer. The epitaxial wafer includes a substrate configured to be doped in a first doping concentration; an epitaxial layer configured to be formed over a first side of the substrate and doped in a second doping concentration lower than the first doping concentration; and a back seal layer configured to be formed over a second side of the substrate and include a layer having a tensile stress, wherein the second side is opposite to the first side, of the substrate.

### CROSS-REFERENCE TO RELATED APPLICATIONS

The present invention claims priority of Korean Patent Application No. 10-2008-0133881 filed on Dec. 24, 2008, which is incorporated herein by reference in its entirety.

### BACKGROUND OF THE INVENTION

1. Field of the Invention

The present invention relates to a semiconductor device and a method for fabricating the same; and, more particularly, to an epitaxial wafer and a method for fabricating the same.

2. Description of Related Art

Generally, an epitaxial wafer is used in a process for fabricating a high power transistor, e.g., a Field Effect Transistor (FET) of trench type, wherein the epitaxial wafer is formed through depositing a grown epitaxial layer having a high-resistance electrode over a silicon substrate having a low-resistance electrode

FIG. 1 is a cross-sectional view illustrating a conventional N-type epitaxial wafer.

Referring to FIG. 1, the conventional N-type epitaxial wafer includes a silicon substrate 101, an epitaxial layer 102 and a back seal layer 103. The epitaxial layer 102 is formed over an upper side of the silicon substrate 101. The back seal layer 103 is formed over a backside of the silicon substrate 101.

The silicon substrate 101 requires a row resistance for improving a current efficiency of a transistor since the silicon substrate 101 is used as a junction region between the epitaxial layer 102 and the back seal layer 103. For lowering the resistance of the silicon substrate 101, the silicon substrate 101 is doped with phosphorous (P), arsenic (As) or antimony (Sb).

The back seal layer 103 is formed to prevent emitting dopants from the backside of the silicon substrate 101 during a pre-bake process at a high temperature of an epitaxial growth process.

However, as illustrated in FIG. 2, since a molecule size of the dopants, e.g., P, as or Sb in the silicon substrate 101 is bigger than one of a silicon (Si) of the silicon substrate 101, a lattice constant of the substrate 101 is increased when the silicon substrate 101 is doped in a high concentration. The N-type epitaxial wafer is bowed by the lattice constant difference between the silicon (Si) and the dopants, e.g., P, As or Sb of the silicon substrate 101 as illustrated in FIG. 3.

### SUMMARY OF THE INVENTION

Embodiments of the present invention are directed to providing an epitaxial wafer and a method for fabricating the same, which can prevent a bowing phenomenon of the epitaxial wafer.

Other objects and advantages of the present invention can be understood by the following description, and become apparent with reference to the embodiments of the present invention. Also, it is obvious to those skilled in the art to which the present invention pertains that the objects and advantages of the present invention can be realized by the means as claimed and combinations thereof.

In accordance with an aspect of the present invention, there is provided an epitaxial wafer, including: a substrate configured to be doped in a first doping concentration; an epitaxial layer configured to be formed over a first side of the substrate and doped in a second doping concentration lower than the first doping concentration; and a back seal layer configured to be formed over a second side of the substrate and include a layer having a tensile stress, wherein the second side is opposite to the first side of the substrate.

In accordance with another aspect of the present invention, there is provided a method for fabricating an epitaxial wafer, including: forming a substrate being doped in a first doping concentration; forming an epitaxial layer on a first side of the substrate and doped in a second doping concentration lower than the first doping concentration; and forming a back seal layer on a second side of the substrate and include a layer having a tensile stress, wherein the second side is opposite to the first side, of the substrate.

### BRIEF DESCRIPTION OF THE DRAWINGS

FIG. 1 is a cross-sectional view illustrating a conventional epitaxial wafer.

FIG. 2 illustrates a lattice constant of a silicon substrate doped in high concentration and an epitaxial layer doped in a low concentration according to the prior art.

FIG. 3 is a cross-sectional view illustrating a bowing of the epitaxial wafer according to the prior art.

FIG. 4 is a cross-sectional view illustrating an epitaxial wafer in accordance with a first embodiment of the present invention.

FIG. 5 is a cross-sectional view illustrating an epitaxial wafer in accordance with a second embodiment of the present invention.

FIG. 6 is a cross-sectional view illustrating an epitaxial wafer in accordance with a third embodiment of the present invention.

FIG. 7 is a cross-sectional view illustrating an epitaxial wafer in accordance with a fourth embodiment of the present invention.

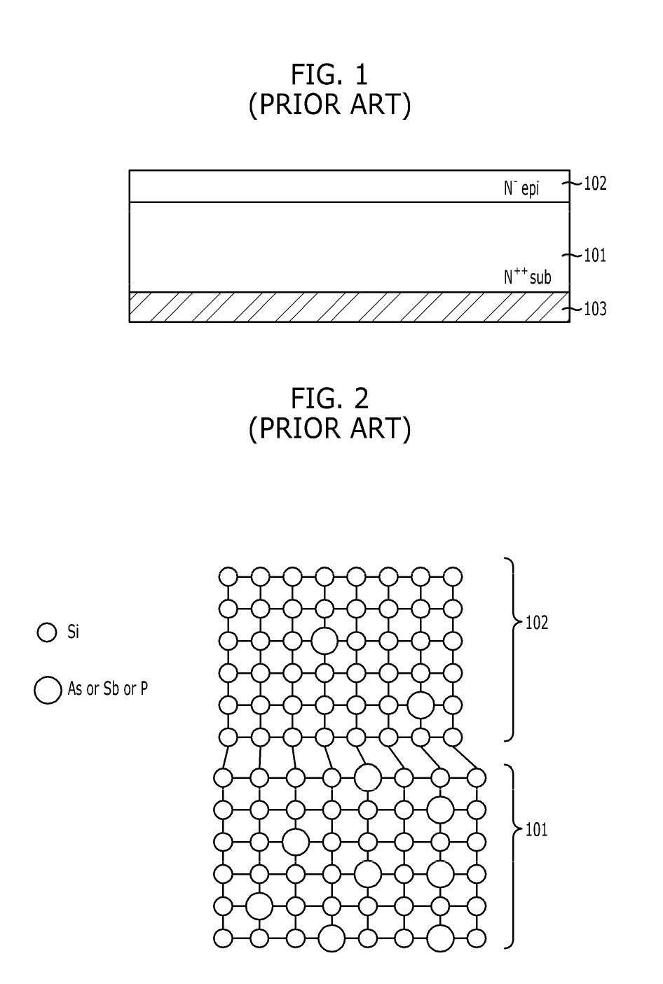

### DESCRIPTION OF SPECIFIC EMBODIMENTS

In the figures, the dimensions of layers and regions are exaggerated for charity of illustration. It will also be understood that when a layer or a film is referred to as being ‘on’ another layer or silicon substrate, it can be directly on the other layer or silicon substrate, or intervening layers may also be present. Furthermore, it will be understood that when a layer is referred to as being ‘under’ another layer, it can be directly under, and one or more intervening layers may also be present. In addition, it will also be understood that when layer is referred to as being ‘between’ two layers, it can be the only layer between the two layers, or one or more intervening layers may also be present.

The advantages, features and aspects of the invention will become apparent from the following description of the embodiments with reference to the accompanying drawings, which is set forth hereinafter. In the description on each embodiment, a silicon substrate will be descried as an example of a N-type doped silicon substrate. However, the spirit and scope of the present invention are not limited to the semiconductor device.

Hereinafter, an epitaxial wafer and a method for fabricating the same will be described in detail with reference to the accompanying drawings.

### Embodiment 1

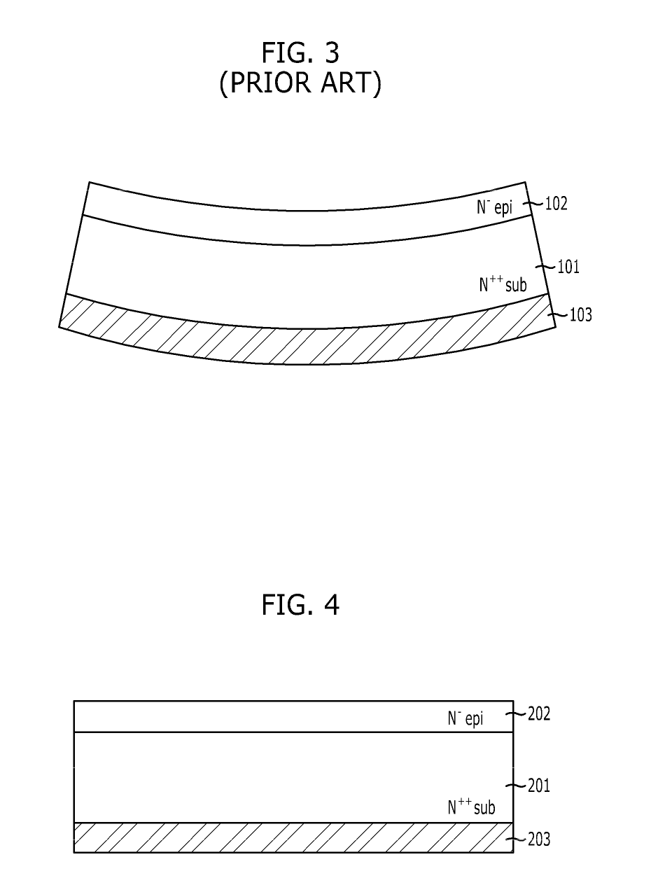

FIG. 4 is a cross-sectional view illustrating an epitaxial wafer in accordance with a first embodiment of the present invention. In the description on each embodiment, a silicon substrate will be descried as an example of an N-type doped silicon substrate. However, the spirit and scope of the present invention are not limited to the semiconductor device.

Referring to FIG. 4, an epitaxial wafer in accordance with the first embodiment includes a silicon substrate 201, an epitaxial layer 202 and a back seal layer 203. A doping concentration of the silicon substrate 201 is greater than a doping concentration of epitaxial layer 202. The epitaxial layer 202 is formed over an upper side of the silicon substrate 201. The back seal layer 203 includes a layer having a tensile stress and is formed over a backside of the silicon substrate 201.

The silicon substrate 201 includes a bulk wafer. Any one of a reclaimed wafer, a test wafer and a prime wafer is used as the silicon substrate 201. For example, the silicon substrate 201 may have a resistance ranging from approximately 10⁻⁵ to approximately 10⁻¹ Ω*cm. Any one of an N-type wafer, a P-type wafer and an intrinsic wafer may be used as the silicon substrate 201. The silicon substrate 201 is doped with phosphorous (P), arsenical (As) or antimony (Sb).

The epitaxial layer 202 is doped in a doping concentration having a resistance ranging from approximately 1 to approximately 50 Ω*cm. Any one of an N-type wafer, a P-type wafer and an intrinsic wafer may be used as the epitaxial layer 202. The epitaxial layer 202 is formed at a temperature ranging from approximately 900° C. to approximately 1200° C. and under a pressure ranging from approximately 10 Torr to approximately 760 Torr in an epitaxial growth process to thereby form the epitaxial layer 202 being doped with phosphorous (P), arsenical (As) or antimony (Sb). Any one of Silane Dichloro Silane (DCS) and Tri Chloro Silane (TCS) is used as a source gas in the epitaxial growth process. The source gas is not limited to the referred gas and all silicon gas may be used as the source gas. Diborane (B₂H₆), arsane (AsH₃) and phosphane (PH₃) may be used as an addictive gas for defining a doping type of the epitaxial layer 202 in the epitaxial growth process. The arsane (AsH₃) or the phosphane (PH₃) is used as addictive gas to perform the epitaxial layer 202 having a doping type of N-type. The diborane (B₂H₆) is used as addictive gas to perform the epitaxial layer 202 having a doping type of P-type.

The back seal layer 203 includes a layer having the tensile stress. A silicon nitride (SiN) layer may be used as the layer having a tensile stress. The thickness of the silicon nitride (SiN) layer depends on the doping concentrations of the silicon substrate 201 and the epitaxial layer 202. That is, the silicon nitride (SiN) layer become thicker as the doping concentration of the silicon substrate 201 become greater and the doping concentration of the epitaxial layer 202 is lower.

A bowing phenomenon of the epitaxial wafer of the prior art may be prevented by using the silicon nitride (SiN) layer, which has the tensile stress in characteristic as the back seal layer 203. That is, the bowing phenomenon caused by the epitaxial growth process may be canceled since the silicon nitride (SiN) layer bows an opposite direction to bowing of the epitaxial wafer shown in FIG. 3, due to the tensile stress.

### Embodiment 2

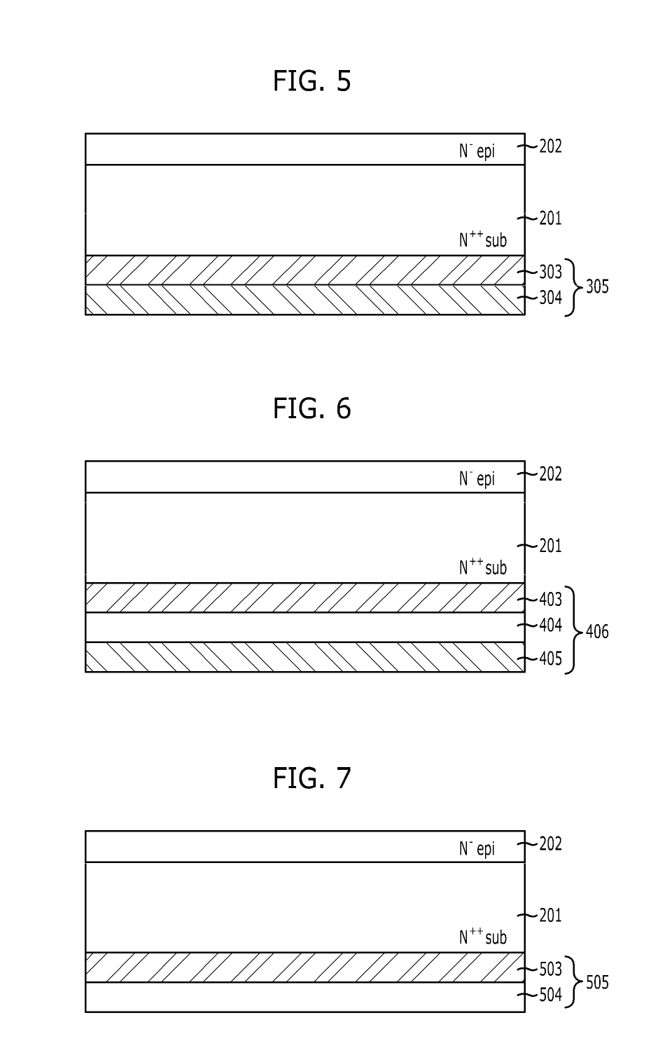

FIG. 5 is a cross-sectional view illustrating an epitaxial wafer in accordance with a second embodiment of the present invention.

Referring to FIG. 5, the epitaxial wafer in accordance with the second embodiment includes a back seal layer 305 having a tensile stress as well as the first embodiment thereof. The back seal layer 305 includes a polysilicon layer 303 and a silicon nitride layer 304. The polysilicon layer 303 is formed over a backside of the silicon substrate 201 to prevent dopants from being emitted to a backside of the silicon substrate 201. The silicon nitride layer (SiN) 304 is formed over a backside of the polysilicon layer 303 to prevent the bowing phenomenon of the epitaxial wafer.

### Embodiment 3

FIG. 6 is a cross-sectional view illustrating an epitaxial wafer in accordance with a third embodiment of the present invention.

Referring to FIG. 6, the epitaxial wafer in accordance with the third embodiment includes a back seal layer 406 having a tensile stress. The back seal layer 406 includes a stacked layer formed through sequentially depositing a polysilicon layer 403, a silicon oxide layer 404 and a nitride layer 405. The polysilicon layer 403 is formed over a backside of the silicon substrate 201. The silicon oxide layer 404 is formed over a backside of the polysilicon layer 403. The silicon nitride layer 405 is formed over a backside of the silicon oxide layer 404. The polysilicon layer 403 and the silicon oxide layer 404 are formed to prevent dopants from being emitted to the backside of the silicon substrate 201. The nitride layer 405 is formed to prevent the bowing phenomenon of the epitaxial wafer 202.

### Embodiment 4

FIG. 7 is a cross-sectional view illustrating an epitaxial wafer in accordance with a fourth embodiment of the present invention.

Referring to FIG. 7, the epitaxial wafer in accordance with the fourth embodiment includes a back seal layer 505 having a tensile stress. The back seal layer 505 includes a stacked layer formed through sequentially depositing a silicon oxide layer 503 and a silicon nitride (SiN) layer 504. The silicon oxide layer 503 is formed over a backside of the silicon substrate 201. The silicon nitride (SiN) layer 504 is formed over a backside of the silicon oxide layer 503. The silicon oxide layer 503 is formed to prevent dopants from being emitted to a backside of the silicon substrate 201. The silicon nitride (SiN) layer 504 is formed to prevent the bowing phenomenon of the epitaxial wafer.

In the description on the first to fourth embodiments, the polysilicon layer 303 and 403, the silicon oxide layer 404 and 503 and the silicon nitride layer 304, 405 and 504 are formed before forming the epitaxial layer 202 is formed over the silicon substrate 201. The polysilicon layer 303 and 403, the silicon oxide layer 404 and 503 and the silicon nitride layer 304, 405 and 504 are formed over an upper side as well as the backside of the silicon substrate 201 during the deposition process. After the deposition process, the polysilicon layer, the silicon oxide layer and the nitride layer on the silicon substrate 201 may be removed through a dry etch process, e.g., an etch back process or a Chemical Mechanical Polishing (CMP) although not illustrated in the drawing. The polysilicon layer, the silicon oxide layer and the silicon nitride layer is selectively remained on the backside of the silicon substrate 201.

In the description on the first to fourth embodiments, the polysilicon layer, the silicon oxide layer and the silicon nitride layer may be formed through a Low Pressure Chemical Vapor Deposition (LPCVD), respectively. The epitaxial layer 202 may be formed through the LPCVD or the Remote Plasma Chemical Vapor Deposition (RPCVD).

The epitaxial silicon wafer being fabricated by the first to fourth embodiment is used in field of an Integrated Circuit (IC), a Dynamic Random Access Memory (DRAM) and a flash memory device as well as a Charge Coupled Device (CCD), a CMOS Image Sensor (CIS), a LCD Driver IC (LDI).

As described above the wafer and the method the same of the present invention can be applied to the semiconductor device to prevent the bowing phenomenon the epitaxial wafer is bowed during an epitaxial growth process by forming the back seal layer including the layer having a tensile stress over the backside of the epitaxial wafer.

While the present invention has been described with respect to the specific embodiments, it will be apparent to those skilled in the art that various changes and modifications may be made without departing from the spirit and scope of the invention as defined in the following claims.

What is claimed is:

1. An epitaxial wafer, comprising:
a substrate configured to be doped in a first doping concentration;
an epitaxial layer configured to be formed over a first side of the substrate and doped in a second doping concentration lower than the first doping concentration; and
a back seal layer configured to be formed over a second side of the substrate and include a layer having a tensile stress,
wherein the second side is opposite to the first side of the substrate.

2. The epitaxial wafer of claim 1, wherein the layer having the tensile stress includes a silicon nitride layer.

3. The epitaxial wafer of claim 1, wherein the back seal layer includes:
a polysilicon layer configured to be formed over the substrate; and
a silicon nitride layer configured to be formed over the polysilicon layer.

4. The epitaxial wafer of claim 1, wherein the back seal layer includes:
a polysilicon layer configured to be formed over the substrate;
a silicon oxide layer configured to be formed over the polysilicon layer; and
a silicon nitride layer configured to be formed over the silicon oxide layer.

5. The epitaxial wafer of claim 1, wherein the back seal layer includes:
a silicon oxide layer configured to be formed over the substrate; and
a silicon nitride layer configured to be formed over the silicon oxide layer.

6. A method for fabricating an epitaxial wafer, comprising:
forming a substrate being doped in a first doping concentration;
forming an epitaxial layer over a first side of the substrate and doped in a second doping concentration lower than the first doping concentration; and
simultaneously forming a back seal layer over the first side and a second side of the substrate and include a layer having a tensile stress, wherein the second side is opposite to the first side of the substrate,
removing the back seal layer over the first side through an etch process.

7. The method of claim 6, wherein the layer having the tensile stress is a silicon nitride layer.

8. The method of claim 6, wherein said forming a back seal layer includes:
forming a polysilicon layer on the substrate; and
forming a silicon nitride layer on the polysilicon layer.

9. The method of claim 6, wherein said forming the back seal layer includes:
forming a polysilicon layer on the substrate;
forming a silicon oxide layer on the polysilicon layer; and
forming a silicon nitride layer on the silicon oxide layer.

10. The method of claim 6, wherein said forming the back seal layer includes:
forming a silicon oxide layer on the substrate; and
forming a silicon nitride layer on the silicon oxide layer.

11. The method of claim 6, wherein the substrate and the epitaxial layer is doped with any one of N-type dopants and P-type dopants.

12. The method of claim 11, wherein the dopants are selected from any one of phosphorous (P), arsenic (As) and antimony (Sb).

13. The method of claim 6, wherein the forming the back seal layer is performed before the forming the epitaxial layer.

14. The method of claim 6, wherein the etch process includes an etch back process.

15. The method of claim 6, wherein the etch process includes a Chemical Mechanical Polishing (CMP).
